(19) United States
(12) Patent Application Publication
(10) Pub. No.: US 2008/0261375 A1
(43) Pub. Date: Oct. 23, 2008

(54) Method of Forming a Semiconductor Device Having a Dummy Feature

(75) Inventors: Kevin Lucas, Meylan (FR); Robert Boone, Grenoble (FR); Judith Mueller, Grenoble (FR); Rainer Thoma, Crolles (FR); Yves Rody, Crolles (FR)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: Freescale Semiconductor, Inc., Austin, TX (US)

(21) Appl. No.: 12/097,474

(22) PCT Filed: Dec. 14, 2005
(86) PCT No.: PCT/EP2005/014232

§ 371 Date: Jun. 13, 2008

(51) Int. Cl. H01L 21/302; H01L 21/8234

(52) U.S. Cl. 438/400; 438/689; 257/E21.616; 257/E21.214

(57) ABSTRACT

A method for forming a semiconductor device includes identifying an area that comprises an active device region, wherein the area has a perimeter at a first location and at least a portion of the edge of the active device region is coincident with at least a portion of the perimeter, expanding the perimeter to a first distance away from the first location, wherein the first distance defines a first point of a dummy feature, determining a second point of the dummy feature, adding the dummy feature to a layout using the first point and the second point, and using the layout to form a layer in a semiconductor device.

### FIELD OF THE INVENTION

This invention relates generally to semiconductor devices, and more specifically, to forming semiconductor devices with dummy etch features.

### BACKGROUND OF THE INVENTION

To increase device speed, the lengths of gate electrodes are decreasing. At the small dimensions that are currently used, it is important that the gate electrode has straight sidewalls. If the top of the gate electrode is etched more than the bottom, then the small area of the top of the gate electrode makes it difficult to salicide the top of the gate electrode. If, instead, the bottom of the gate electrode is narrower than the top, a shadow effect occurs making it difficult to implant source and drain regions adjacent the gate electrode. The profile of the sidewalls is predominantly determined by etching.

Etching also can create a nonuniformity of the critical dimension of features, such as gate electrodes, across the wafer. For example, the dimension of a feature in one area of the wafer may be a larger than the dimension of another feature in a different area of the wafer even though the two features are intended to have the same dimension. This non-uniformity of dimension can be caused by non-uniformity in the location of neighboring features. This nonuniformity in neighbor feature location is typically most important within 1 to 10 microns of the feature with critical dimension. In addition to affecting the critical dimension of the feature the nonuniformity of neighboring feature location also negatively impacts the final gate profile of the feature.

One proposal for improving the dimension and gate profile uniformity is to have dummy features placed adjacent isolated critical feature edges. This may be performed manually by placing dummy features, having predetermined shapes and dimensions near active circuit features. However, this is time consuming and subject to error. Hence, a fast, robust, and efficient method for placing dummy features is needed.

### SUMMARY OF THE INVENTION

The present invention provides a method for forming a semiconductor device having a dummy feature as described in the accompanying claims.

### BRIEF DESCRIPTION OF THE DRAWINGS

The present invention is illustrated by way of example and is not limited by the accompanying figures, in which like references indicate similar elements.

FIG. 1 illustrates a top down view of a portion of an example of a layout of a semiconductor device;

FIG. 2 illustrates the layout of FIG. 1 illustrating a perimeter of an area;

FIG. 3 illustrates the layout of FIG. 1 after moving a perimeter a first distance in accordance with an embodiment of the present invention;

FIG. 4 illustrates the layout of FIG. 1 after moving a perimeter a second distance in accordance with an embodiment of the present invention;

FIG. 5 illustrates the layout of FIG. 1 after adding a first dummy feature and a second dummy feature in accordance with an embodiment of the present invention;

FIG. 6 illustrates the layout of FIG. 1 after enlarging the second dummy features in accordance with an embodiment of the present invention;

FIG. 7 illustrates the layout of FIG. 6 after a third dummy feature is added underneath the second dummy features in accordance with an embodiment of the present invention;

FIG. 8 illustrates a top down view of another portion of a layout of a semiconductor device in accordance with an embodiment of the present invention;

FIG. 9 illustrates a top down view of FIG. 8 after enlarging a sixth active feature or forming a third dummy feature; and

FIG. 10 illustrates a top down view of FIG. 5 after forming a third dummy feature.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE PREFERRED EMBODIMENTS

Three terms are defined below to aid in the understanding the specification.

1. Active circuit features are features that correspond to the designed circuitry for a semiconductor device. The active features include portions of transistors, capacitors, resistors, or the like. Active features include power supply features, which are designed to operate at a substantially constant potential, and signal features, which are designed to operate at one potential under one set of electronic conditions and a different potential at another set of electronic conditions. Active circuit features are not features that help control the processing of a substrate, such as alignment marks, structures for measuring dimensions of features (“CD bars”), electrical test structures, and the like. Active feature are also not features having a primary (most important) function of protecting a semiconductor device from post-fabrication environmental conditions, such as an edge ring seal around a die.

2. Dummy features include features printed onto a semiconductor device substrate, where the features are not any of the other types of features described above. Different types of dummy features are used in semiconductor devices for various reasons. Dummy bit lines are used in memory arrays along the outermost edges to allow all the active bit lines in the array to be uniformly patterned. Unlike dummy bit lines, dummy etch features are dummy features added at a feature level of a mask of a semiconductor device to improve etching characteristics at the current or a subsequently formed level. A dummy etch feature is not required for the proper operation of a device.

3. Active device area is the portion of the die that is used in conjunction with the active circuit features to form a device. The active device area does not include the peripheral area of a die (i.e., the portion of a die that lies between the integrated circuit area and the scribe lines) or any insulated regions on the die.

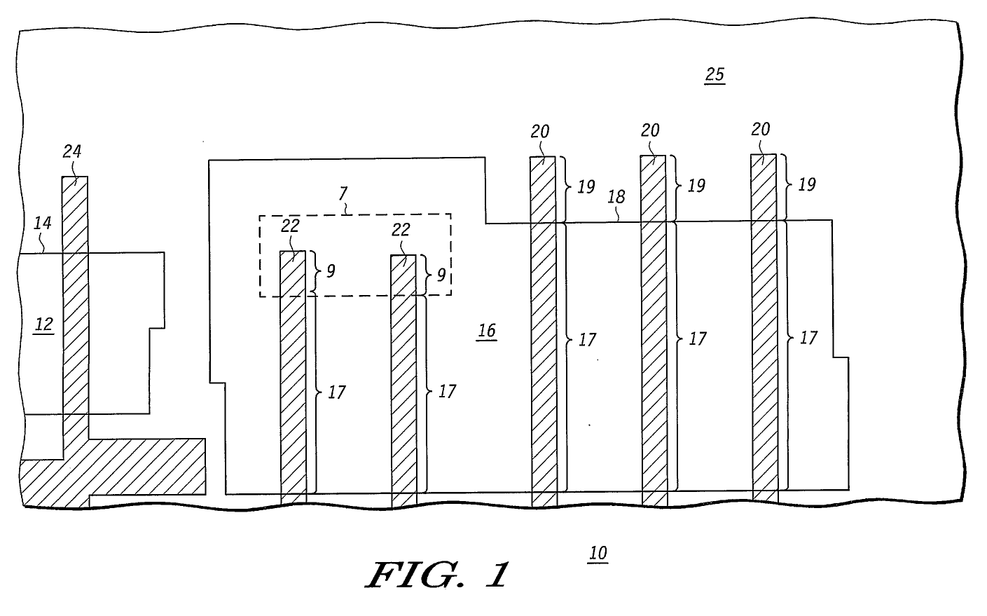

FIG. 1 illustrates a portion of a layout 10 used to form a semiconductor device. A skilled artisan recognizes that there may be layers and features underneath the layout 10, but since the present invention is, for the most part, composed of layers, electronic components, and circuits known to those skilled in the art, details will not be explained in any greater extent than that considered necessary as illustrated below, for the understanding and appreciation of the underlying concepts of the present invention and in order not to obfuscate or distract from the teachings of the present invention.

The layout 10 includes first active circuit features 20, second active circuit features 22, and third active circuit features 24. In one embodiment, the first, second, and third active circuit features 20, 22, and 24 are all portions of gate electrodes and may be any suitable gate electrode material, such as polysilicon. Portions 17 of the first active circuit features 20 and the second active circuit features 22 are within the first active device area 16, and portions 19 of the first active circuit feature 20 are not within the active device area 16. Portions 9 of the second active circuit features 22 are within a cut-out region 7 of the first active device area 16. The cut-out region 7 is formed so that the end of the second active circuit features 22 does not end on the first active device area 16. In one embodiment, the cut-out region 7 is an insulating layer. Portions (not marked) of the third active circuit feature 24 are within the second active device area 12. The first active device area 16 has a perimeter 18 and the second active device area 12 has a perimeter 14. In one embodiment, the first active device area 16 and the second active device area 12 are a portions of the semiconductor substrate that are doped with a p-type or n-type dopant; the first active device area 16 and the second active device area 12, may be doped the same conductivity or different conductivities. The underlying semiconductor substrate, which may be the exposed region 25, can be any semiconductor material or combinations of materials, such as gallium arsenide, silicon germanium, silicon-on-insulator (SOI) (e.g., fully depleted SOI (FDSOI)), silicon, monocrystalline silicon, the like, and combinations of the above. The p-type dopant can be any suitable dopant, such as boron if the semiconductor substrate is silicon, and the n-type dopant can be any suitable dopant, such as phosphorus if the semiconductor substrate is silicon. Alternatively, the exposed region 25 may be an insulating layer or a combination of an insulating layer and a semiconductor layer.

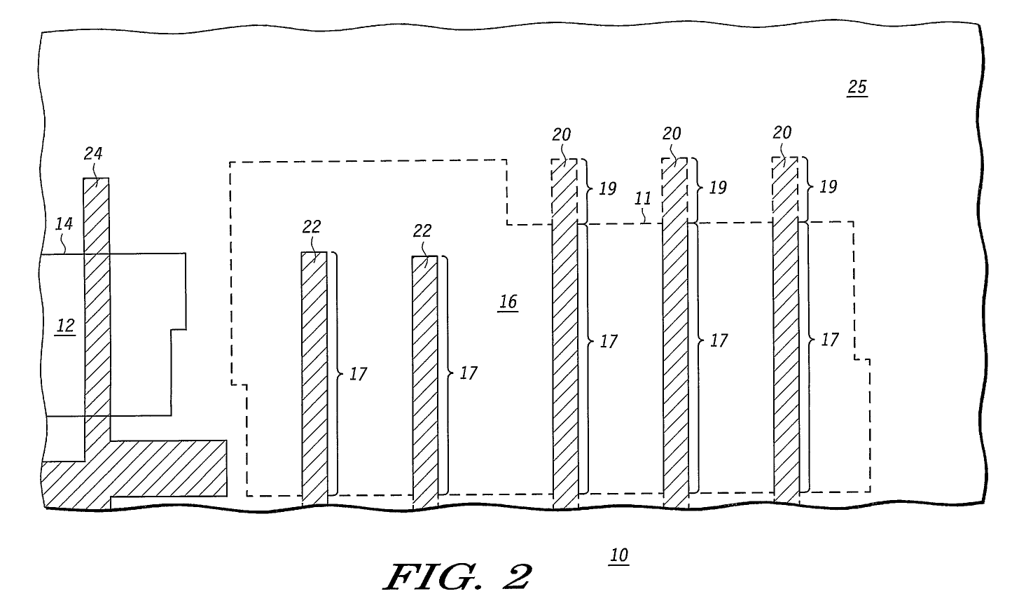

At least one dummy feature is added to the layer 10. In the embodiment illustrated in the figures, two dummy features are added. In one embodiment, the location and shapes of the dummy features are determined by expanding the perimeter of an area. First, the area is identified by choosing an area that includes an active device region and may include portions of active circuit features that are not within or overlie the active device region. Next, the perimeter of the active device region is defined. In one embodiment, the area includes the first active device region 16 and any features or portions 17, which are within the active device region 16, so that the perimeter of the area is the perimeter 18 of the active device region 16. In another embodiment, the area includes the first active region 16, features within the active device region 16, and features and portions of the first circuit devices 20 that are not within the active device region 16, such as portions 19 of the first circuit devices 20. The portions 19 of the first circuit devices 20 may be part of the area being defined to avoid placing a dummy feature too close to a circuit device. In this embodiment, the perimeter of the area is marked by the dotted line 11 in FIG. 2. In this embodiment, the perimeter of the area includes the perimeter 18 (FIG. 1) of the active device region 16 except where the first circuit devices 20 extend past the active device region. In the locations where the perimeter 18 (FIG. 1) is not part of the perimeter of the area, the perimeter of the area in these locations is the perimeter of the portions 19. Therefore, at least a portion of the perimeter is coincident with a portion of the perimeter 18 (FIG. 1) of active device region 16. As described above, in one embodiment, the perimeter of the area may also be coincident with a portion of the perimeter of the portions 19.

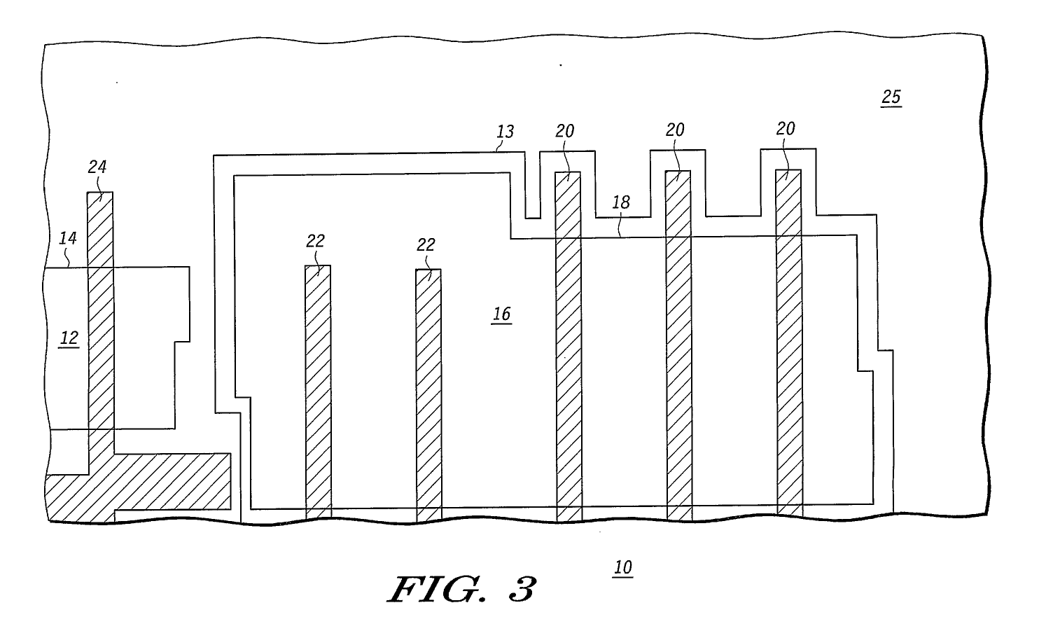

Once the perimeter is defined, it is moved a first distance away from its original location. In other words, the perimeter is moved so that the area defined by the perimeter is enlarged. As shown in the embodiment in FIG. 3, the perimeter 11 is moved a first distance to the line marked 13. In one embodiment, this is done using software, such as design rule checking (DRC) software. One type of DRC software is Calibre® from Mentor Graphics® headquartered in Wilsonville, Oreg. In another embodiment, the perimeter is moved to a first distance manually. As will better be understood after further explanation, if a dummy feature is to be placed, a point on the perimeter at a first distance will be at least a first point of the dummy feature.

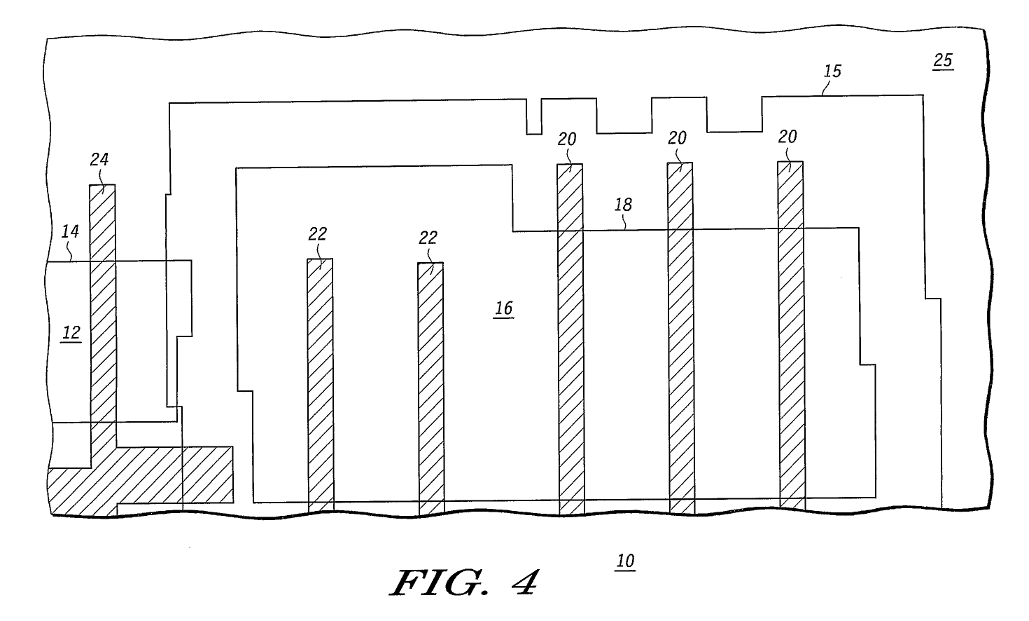

After expanding the perimeter to the first distance, a second point of the dummy feature is defined. In one embodiment, this is performed by moving the perimeter to a second distance, where the second distance is further away than the first distance. As shown in the embodiment in FIG. 4, the perimeter 11 is moved a first distance to the line marked 15. The perimeter can be moved by any method used to move the perimeter to the first distance, although the same method may not be used for moving the perimeter both a first distance and a second distance. In another embodiment, the second point is determined by expanding the first perimeter, expanding perimeters of adjacent areas (not shown), the like, or combinations of the above.

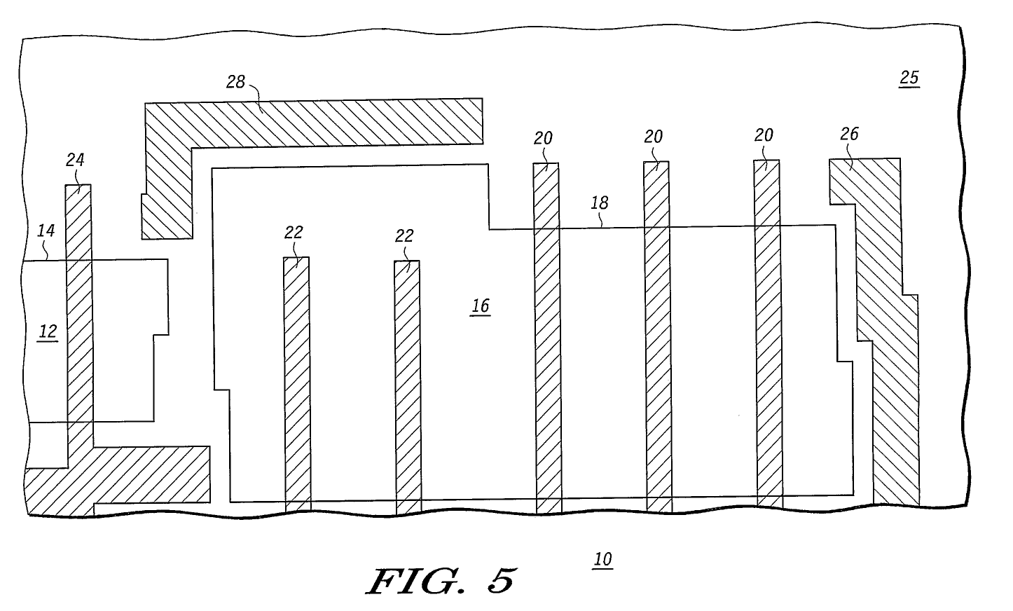

As shown in FIG. 5, after at least the second point of the dummy feature is defined, at least one dummy feature is added to the layout. In one embodiment, a plurality of dummy features is added. However, places where the addition of a dummy feature will be too close to active circuit features or active regions, dummy features (or portions thereof) are not added. For example, a first dummy feature 26 and a second dummy feature 28 are added to the layout, but no dummy features are formed over the second active device area 12 and third active circuit feature 24. The layout 10 now includes the first dummy feature 28 and the second dummy feature 26. In a preferred embodiment, the first and second dummy features 28 and 26 are etch dummy features because they are used to improve the etch profile of surrounding active circuit features. In order to assist with etch processing, the dummy features are formed on the reticle and on the semiconductor device. In one embodiment, the first and second dummy features 28 and 26 may be the same materials as each other or any of the first, second, and third active circuit features 20, 22, and 24 and formed at the same time using the same processing as the first, second, and third active circuit features 20, 22, and 24.

Subsequent processes may include an optical proximity correction (OPC) process, as performed in the prior art, to assist with the printing of the first, second, and third active circuit features 20, 22, and 24. However, in one embodiment, the first and second dummy features 28 and 26 are not used in the OPC process. This can be achieved by forming a layer in the DRC software that includes only the dummy features and by not including this layer in those that are used in the OPC process.

The first and second dummy features 26 and 28 are placed using at least the first point and second point previously determined. In the embodiment illustrated in the figures, the edges of the dummy features 26 and 28 that are closest to the original (unmoved) location of the perimeter 11 were determined and are contiguous with the location of the perimeter when moved a the first distance 13, and the edges that are farthest from the perimeter 11 were determined and are contiguous with the location of the perimeter when moved to the second distance 15. Thus, the difference between the first and second distances may be the width of a dummy feature because each of the first and second points is coincident with an edge of the dummy feature. In one embodiment, the difference between the first and second distances is ½ the width of a dummy feature because the first point defined a point on the edge of the dummy feature and the second point defined a point in the center of the dummy feature. Because the perimeter of the active circuit region includes, in the embodiment shown in FIG. 1, the active region 16 and the portions 19, the first and second dummy features 26 and 28 each have edges that corresponds to the shape of the perimeter adjacent the dummy features 24 and 26. The first dummy feature 26 protects the ends of the second active circuit features 22 and the second dummy feature 28 protects the edges of the first active circuit features 24 because both the line ends and edges are prone to deformation during subsequent processing, such as etching.

After forming at least one dummy feature, modifications to the layout, which now includes a dummy feature or a plurality of dummy features, may be made to minimize the electrical and processing, such as etch, effects of forming the dummy features. In other words, after adding the dummy features, the layout may be optimized. Any of the approaches discussed below can be used alone or in combination with other approaches discussed.

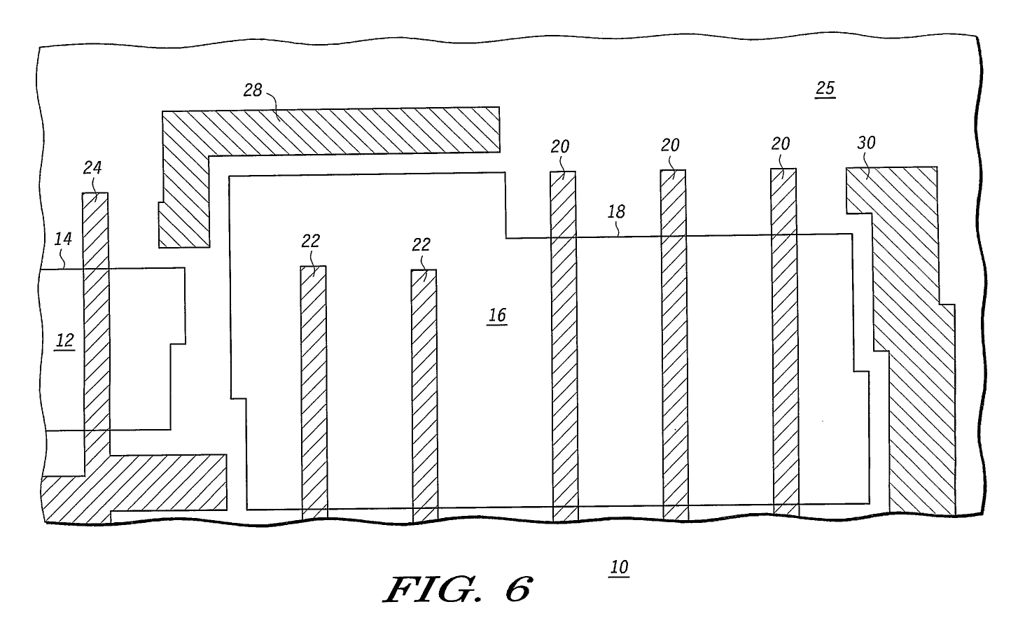

One approach to optimize the layout that includes dummy features is to modify the dummy features. In one embodiment, a dummy feature may be modified to adjust for the subsequent etch processing. In one embodiment, the dummy feature may be too far away from at least a portion of an active circuit feature that the dummy feature may not achieve the critical dimension of the active circuit feature (or portion thereof). In other words, the dummy feature may not prevent the active circuit feature (or potion thereof) from being modified from the desired dimensions during etch. This may occur because the dummy feature is too far from the active circuit feature because the etch profile of a feature is determined on a small size scale (less than approximately 10 microns, which in one embodiment is approximately 1-10 microns, or 1-5 microns). For example, without adjusting the dummy feature the active circuit feature may be etched so that it is too narrow. Thus, the dummy feature may need to be moved closer to the active circuit feature or increase in size so that the active circuit feature (or portion thereof) will be the desired dimension after etching. For example, the dummy feature may be increased in area. In the embodiment shown in FIG. 6, at least one edge of the first dummy feature 26 is expanded so that the expanded second dummy feature 30 has a larger area than the (original) first dummy feature 26. Thus, the critical dimension of the active circuit feature determined after etch may be optimized by moving at least an edge of a dummy feature. In one embodiment, this can be performed by using etch simulation to optimize the dimension or profile of the active circuit feature.

In one embodiment, the dummy feature is modified so that it is undoped. Typically, dummy features are doped when the surrounding areas of the dummy features are doped. For simplicity in processing the dummy features are also doped. It is desirable to prevent the dummy features from being doped, which can be performed by shielding them during implantation with a mask (such as photoresist). By having the dummy features undoped resistance is increased and capacitance is decreased. For example, a switching signal adjacent a sensing line may create cross-talk. By forming a dummy feature, the switching line may be affected so that it is too close to the sensing line, especially if the dummy feature is electrically coupled to the switching line which as subsequently explained and shown in FIG. 9 may occur. The closeness of the dummy feature to the switching line creates cross-talk. But if the dummy feature is undoped then conductivity and capacitance, and hence cross-talk, is decreased.

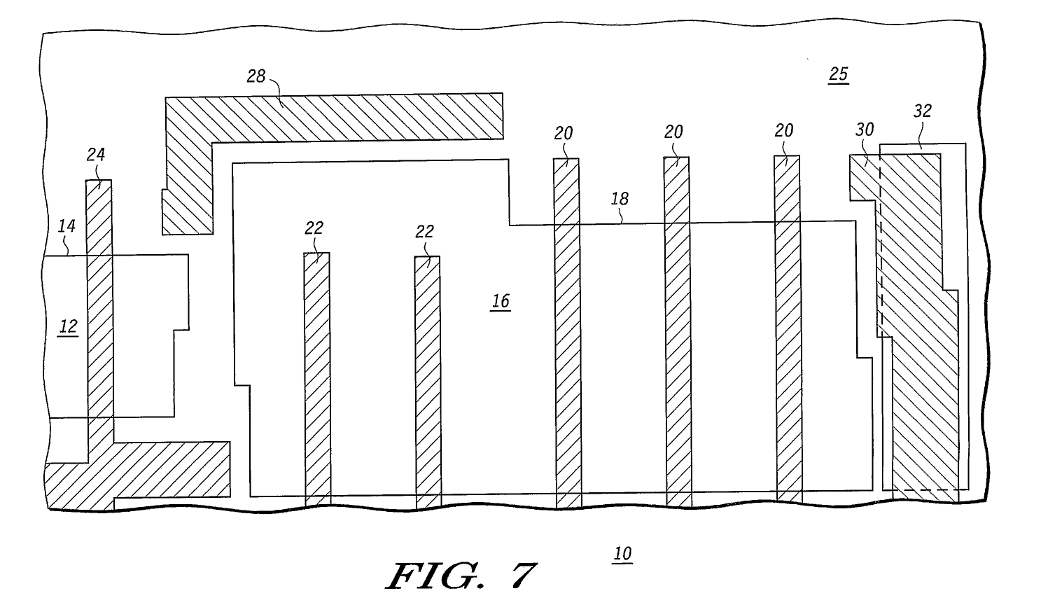

Another way to optimize the layout that includes dummy features is to modify parts of the layout other than the dummy features themselves. In one embodiment, layers underlying the dummy features are modified to affect the capacitance and electrical characteristics of the dummy features. For example, as shown in FIG. 7, a portion of the area underneath the dummy feature, which may be portion of the semiconductor substrate, may be replaced with an underlying layer 32, such as an insulating layer or layers. For example, the same insulating layer or layers used to form the gate dielectric underneath the active circuit features, if they are part of the gate electrode, may be used. In one embodiment, a triple gate oxide is formed underneath the second dummy feature 28, as shown in FIG. 7. In one embodiment, the triple gate oxide 32 is formed with nitrided oxide and has a thickness of approximately 20 to 100 Angstroms. If the same material is used for the underlying layer 32 and the gate dielectric, then the underlying layer 32 can be formed and patterned using conventional processing at the same time the gate dielectric is formed. Subsequently, the active circuit and dummy features are formed. The presence of the underlying layer 32 helps reduce substrate leakage by insulating the semiconductor substrate, which is under the underlying layer 32, from the expanded second dummy feature 30.

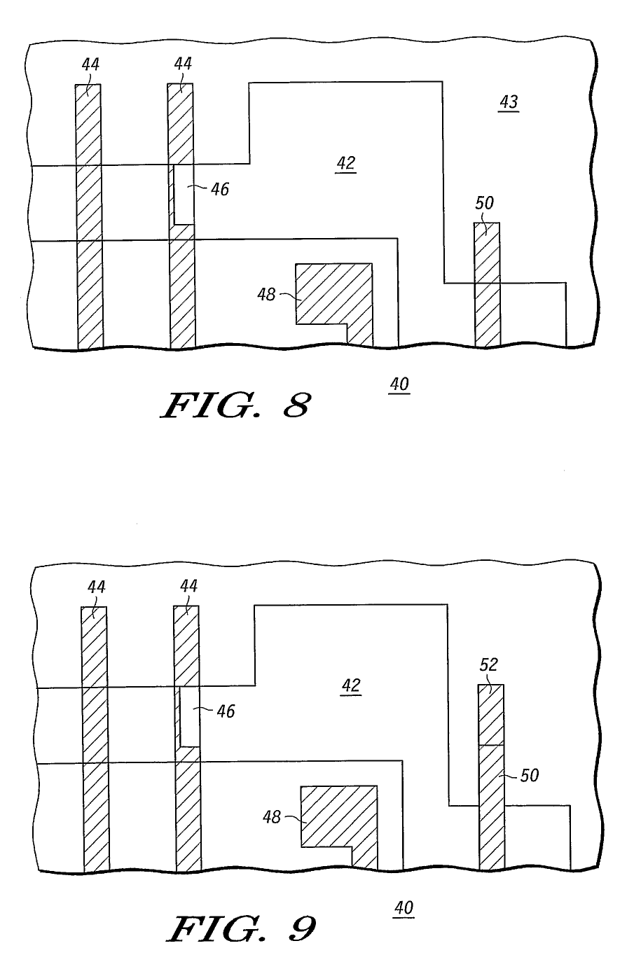

FIGS. 1-7 illustrate how at least one dummy feature can be formed in the layout 10 and how the layout 10 can be modified. Other parts of a semiconductor device or other semiconductor devices will have different layouts, which may result in the dummy features being formed in locations different than that shown in FIGS. 5-7. FIG. 8 illustrates another layout 40 that illustrates different locations for a dummy feature that may arise in a semiconductor device layout. The layout 40 in FIG. 8 is similar to the layout 10 in FIG. 1 in that the layout is of the same layer. The layout 40 includes a third active device region 42 and fourth, fifth, and sixth active circuit features 44, 48, and 50 and region 43, which is similar to region 25 in FIG. 1. (The same materials and processes can be used to form the active device region and active circuit features as those discussed for the equivalent features in FIG. 1.) The portion 46 of the fourth active circuit feature 44 does not have another active circuit feature or a dummy feature nearby. Thus, placing a dummy feature near the portion 46 may be desirable. Using the methods described above, a dummy feature may be placed. In on embodiment, the dummy feature may be placed in contact with the sixth active circuit feature 50. Thus, the third dummy feature 52 may be added to the layout 40 using the same method used for forming the first and second dummy features 26 and 28, but with the first distance being set so that it coincides with the end of the sixth active feature 50.

In one embodiment, instead of spacing a dummy feature from the end of an active circuit feature, the dummy feature may be made continuous with the active circuit feature. As shown in FIG. 9, a third dummy feature 52 is placed in the layout 40 so that it is continuous with the sixth active circuit feature 50. The third dummy feature 52 may or may not be the same width as the sixth active circuit feature 50. If the third dummy feature 52 is the same width as the sixth active circuit feature 50 adding the third dummy feature 52 to the end of the sixth active circuit feature 50 so that the two features are in contact is the same as extending the sixth active circuit feature 50 so it extends past the original end of the active circuit feature 50. In other words, the third dummy feature 52 can be viewed as an extension of the sixth active circuit feature 50.

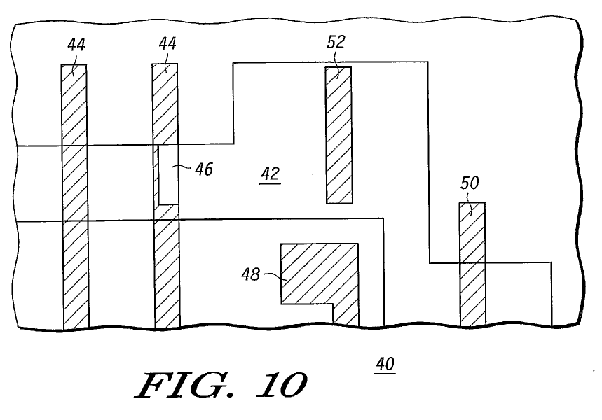

FIG. 10 illustrates that in one embodiment, instead of forming the third dummy feature 52 at the end of the sixth active circuit feature 50, the third dummy feature 52 can be formed over active circuit region 42. Therefore, any dummy feature can be formed over active circuit regions areas or any other area of the layout.

The layouts described above are subsequently used to form layers of a semiconductor device using conventional methods, such as photolithography and etch. Because one skilled in the art knows how to form a semiconductor device using a layout and understands how different layers are used to form a semiconductor device, details of such processing will not be explained in any greater extent than that considered necessary as illustrated above, for the understanding and appreciation of the underlying concepts of the present invention and in order not to obfuscate or distract from the teachings of the present invention.

By now it should be appreciated that there has been provided placement and optimization of dummy features using a fast, robust, and efficient method. Altered model-based proximity correction methods are used to place and optimize dummy features, in one embodiment. The dummy features are optimized for subsequent OPC processes, to reduce their electrical impact, such as substrate leakage, capacitance or latchup. In addition, dummy features are placed near isolated or semi-isolated line-ends to reduce line-end pullback that occurs during etch and can not be prevented by only placing dummy features along the sides of active circuit features.

In one embodiment, a method for forming a semiconductor structure includes providing a semiconductor substrate, identifying an area that comprises an active device region, wherein the area has a perimeter at a first location and at least a portion of the edge of the active device region is coincident with at least a portion of the perimeter, expanding the perimeter to a first distance away from the first location, wherein the first distance defines a first point of a dummy feature, determining a second point of the dummy feature, adding the dummy feature to a layout using the first point and the second point, and using the layout to form a layer in a semiconductor device. In one embodiment, the distance between the first point and the second point defines a width of the dummy feature. In one embodiment, an edge of the dummy feature is modified using an etch simulation result. In one embodiment, the area is characterized by a gate electrode and the perimeter of the area comprises at least a portion of the edge of the gate electrode. In one embodiment, determining a second point of the dummy feature further includes expanding the perimeter to a second distance away from the first location, wherein; the second distance is greater than the first distance, subtracting the first distance from the second distance to determine a width of the dummy feature, and placing the dummy feature so that the edges of the dummy feature are along the first distance and the second distance. In one embodiment, adding the dummy feature is characterized by the placing the dummy feature. In one embodiment, the perimeter is continuous and in another embodiment, the perimeter is broken. In one embodiment, an insulating layer is formed under the dummy feature. In one embodiment, an area adjacent the dummy feature is doped, but the dummy feature is not doped.

In another embodiment, a method for forming a semiconductor device having a dummy feature includes identifying a plurality of active circuit features, wherein the plurality of active circuit features as a group has a perimeter at a first location, expanding the perimeter to a first distance away from the first location, expanding the perimeter to a second distance away from the first location, wherein the second distance is greater than the first distance, subtracting the first distance from the second distance to determine a width of the dummy feature, and placing the dummy feature so that the edges of the dummy feature are along the first distance and the second distance. In one embodiment, the distance between the first point and the second point define a width of the dummy feature.

In the foregoing specification, the invention has been described with reference to specific embodiments. However, one of ordinary skill in the art appreciates that various modifications and changes can be made without departing from the scope of the present invention as set forth in the claims below. For example, although only one layer was described herein, a skilled artisan understands that this can be used for any layer, such as a metal layer. Accordingly, the specification and figures are to be regarded in an illustrative rather than a restrictive sense, and all such modifications are intended to be included within the scope of the present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one. The term “plurality”, as used herein, is defined as two or more than two. The term another, as used herein, is defined as at least a second or more.

1. A method for forming a semiconductor structure, the method comprising:
identifying an area that comprises an active device region, wherein the area has a perimeter at a first location and at least a portion of the edge of the active device region is coincident with at least a portion of the perimeter;
expanding the perimeter to a first distance away from the first location, wherein the first distance defines a first point of a dummy feature;
determining a second point of the dummy feature;
adding the dummy feature to a layout using the first point and the second point; and
using the layout to form a layer in a semiconductor device.

2. The method of claim 1, wherein the distance between the first point and the second point defines a width of the dummy feature.

3. The method of claims 1, wherein an edge of the dummy feature is modified using an etch simulation result.

4. The method of claim 1, wherein the area is characterized by a gate electrode and the perimeter of the area comprises at least a portion of the edge of the gate electrode.

5. The method of claim 1, wherein determining a second point of the dummy feature further comprises:
expanding the perimeter to a second distance away from the first location, wherein;
the second distance is greater than the first distance;
subtracting the first distance from the second distance to determine a width of the dummy feature; and
placing the dummy feature so that the edges of the dummy feature are along the first distance and the second distance.

6. The method of claim 5, wherein adding the dummy feature is characterized by the placing the dummy feature.

7. The method of claim 1, wherein the perimeter is continuous.

8. The method of claim 1, wherein the perimeter is broken.

9. The method of claim 1, wherein forming an insulating layer under the dummy feature.

10. The method of claim 1, wherein doping an area adjacent the dummy feature and not doping the dummy feature.

11. The method of claim 2, wherein determining a second point of the dummy feature further comprises:
expanding the perimeter to a second distance away from the first location, wherein; the second distance is greater than the first distance;
subtracting the first distance from the second distance to determine a width of the dummy feature; and
placing the dummy feature so that the edges of the dummy feature are along the first distance and the second distance.

12. The method of claims 2, wherein an edge of the dummy feature is modified using an etch simulation result.

13. The method of claim 2, wherein the area is characterized by a gate electrode and the perimeter of the area comprises at least a portion of the edge of the gate electrode.

14. The method of claim 2, wherein the perimeter is continuous.

15. The method of claim 2, wherein the perimeter is broken.

16. The method of claim 2, wherein doping an area adjacent the dummy feature and not doping the dummy feature.

17. The method of claim 4, wherein forming an insulating layer under the dummy feature.

18. The method of claim 4, wherein doping an area adjacent the dummy feature and not doping the dummy feature.

19. The method of claim 4, wherein determining a second point of the dummy feature further comprises:
expanding the perimeter to a second distance away from the first location, wherein;
the second distance is greater than the first distance;
subtracting the first distance from the second distance to determine a width of the dummy feature; and
placing the dummy feature so that the edges of the dummy feature are along the first distance and the second distance.

20. The method of claim 9, wherein determining a second point of the dummy feature further comprises:
expanding the perimeter to a second distance away from the first location, wherein;
the second distance is greater than the first distance;
subtracting the first distance from the second distance to determine a width of the dummy feature; and
placing the dummy feature so that the edges of the dummy feature are along the first distance and the second distance.
